(19) United States
(12) Patent Application Publication
(10) Pub. No.: US 2010/0052754 A1
(43) Pub. Date: Mar. 4, 2010

(54) INPUT-SIGNAL RECOVERY CIRCUIT AND ASYNCHRONOUS SERIAL BUS DATA RECEPTION SYSTEM USING THE SAME

(76) Inventor: Chin-Cheng Huang, Taipei (TW)

Correspondence Address: Muncy, Geissler, Olds & Lowe, PLLC, P.O. BOX 1364, FAIRFAX, VA, 22038-1364, US

(21) Appl. No.: 12/393,737

(22) Filed: Feb. 26, 2009

(30) Foreign Application Priority Data
Aug. 29, 2008 (TW) 097133073

(51) Int. Cl. H03K 5/01

(52) U.S. Cl. 327/165

(57) ABSTRACT

An input-signal recovery circuit receives a received data signal and a delay control signal and processes the received data signal. The input-signal recovery circuit includes a data switch detector comprising an input end receiving the received data signal and an output end; a pulse generator comprising a plurality of logic circuits and receiving the received data signal and the delay control signal to generate a plurality of delayed pulse signals; a plurality of switches, each of the switch electrically connected to one corresponding logic circuit, wherein one of the switches is selectively turned on by the data switch detector. The data switch detector selects an output pulse signal from a specific switch when the data switch detector senses a logic state change in the received data signal. The input-signal recovery circuit can prevent data error from error accumulation due to physical difference of crystal oscillators.

### BACKGROUND OF THE INVENTION

1. Field of the Invention

The present invention relates to an input-signal recovery circuit and asynchronous serial bus data reception system using the same, especially to an input-signal recovery circuit recovering data signal by input data signal and asynchronous serial bus data reception system using the same.

2. Description of Prior Art

FIG. 1 shows a schematic diagram of a related art synchronous fully differential bus transceiver system. A transmission sub-system 100 comprises a clock generator 101 generating a timing clock based on an oscillation frequency of an external crystal oscillator 102. A data control circuit 103 in the transmission sub-system 100 sends data signal (Dt+/Dt−) to the receiver sub-system 200. A clock control circuit 104 outputs clock signal (CKt+/CKt−) to the receiver sub-system 200. The data control circuit 103 and the clock control circuit 104 have switch time difference of half period (T/2). The data signal (Dt+/Dt−) and the clock signal (CKt+/CKt−) should be sent to the receiver sub-system 200 through cables of the same length. Therefore, the switch time of the clock signal (CKt+/CKt−) at receiver end is aligned with the center of data eye 201 in the data signal (Dt+/Dt−) as shown in FIG. 2. The optimal setup time 202 and the hold time 203 can be ensured for data integrity in received data.

The transceiver system is a parallel bus transceiver system when multiple pair of data signals (Dt+/Dt−) share the same pair of clock signal (CKt+/CKt−). In this parallel bus transceiver system, the cables used by the data signals (Dt+/Dt−) and the signal (CKt+/CKt−) should have the same or similar length. Skew problem occurs when cable length difference is present among the cables for the data signals (Dt+/Dt−) and the clock signal (CKt+/CKt−). The setup time 202 and the hold time 203 reduce when skew happens, as shown in FIG. 3, and the data transmission rate is limited. The transceiver system is referred to as a synchronous transceiver system when the receiver sub-system 200 refers to the clock signal (CKt+/CKt−) of the transmission sub-system 100 for data reception.

FIG. 4 shows the schematic diagram of a related-art asynchronous serial bus transceiver system. The transceiver system lacks clock signal (CKt+/CKt−) in comparison with that shown in FIG. 1. Therefore, cable cost is reduced and space is saved for printed circuit board. Moreover, the skew problem is not in consideration because clock signal (CKt+/CKt−) is absent. The asynchronous serial bus transceiver system can be used for High-speed USB 480 Mbps, SATA-I 1.5 Gbps, SATA-II 3.0 Gbps, SATA-III 6.0 Gbps, PCI-E 2.5 Gbps and PCI-E-2.0 5.0 Gbps.

In asynchronous serial bus data transceiver system shown in FIG. 4, there is no synchronous timing clock between the transmission sub-system 300 and the receiver sub-system 400. Therefore, data signal Dr and the timing clock signal CKr, as shown in FIG. 5, may have asynchronous problem. As a result, the data signal Dr and the timing clock signal CKr have loss in setup time or hold time. When setup time or hold time is unacceptably small, data integrity is influenced. As shown in FIG. 6, the setup time 401 is unacceptably small, and the clock signal CKr in Nth period triggers the data D−1 in (N−1)th period. As shown in FIG. 7, the hold time 402 is unacceptably small, and the clock signal CKr in Nth period triggers the data D+1 in (N+1)th period. In both situations, data error occurs.

FIG. 8 shows the schematic diagram of another asynchronous serial bus transceiver system. Take USB 2.0 as example, 15 KJ pairs sync signals are sent to the receiver sub-system 600 when the bus exits idle state. As shown in FIG. 9, 2 K signals are sent after the 15 KJ pairs sync signals, where K=0 and J=1. The phase detector 602 shown in FIG. 8 senses the rising edge and the falling edge of the sync signals during the sync period (including 15 KJ pairs sync signals and 2 K signals). The phase detector 602 controls the delay lock loop (DLL) 603 to generate triggering clock having T/2 time difference with the rising edge of data signal (in this cases, the 15 KJ pairs sync signal). After the sync period, the triggering clock generated by the DLL 603 is used to trigger succeeding data signals.

The above-mentioned circuit does not consider the physical difference of crystal oscillators 501, 601 of the transmission sub-system 500 and the receiver sub-system 600. In USB 2.0 specification, the error tolerance is 479.760 Mb/s to 480.240 Mb/s, while the target value is 480 Mb/s. Counted in bit time (or data length), the error tolerance is 2.0843755 ns and 2.0822921 ns, which has difference of 0.0020834 ns. When transmission sub-system 500 has timing clock of 479.760 Mb/s and the receiver sub-system 600 has timing clock of 480.240 Mb/s, the 1000th triggering clock is aligned with the 999th data signal, as shown in FIG. 10, even though the first triggering clock is aligned with the first data signal. Data transmission error therefore occurs. The phase detector 602 and the DLL 603 use only 15 KJ pairs sync signals to modify triggering clock at the beginning of data transmission. The succeeding data signals might contain two or more successive logic 0 signals or two or more successive logic 1. The phase detector 602 and the DLL 603 cannot further modify the triggering clock after data transmission is started.

Moreover, US pre-grant publication No. 20070009072 discloses apparatus and method for calibrating the frequency of a clock and data recovery (CDR) circuit. The gated voltage-controlled oscillator generates a recovered clock signal based on the data signal input to the CDR circuit. A frequency control loop continuously calibrates the gated voltage-controlled oscillator in such a way that the frequency of the clock signal generated by the gated voltage-controlled oscillator continues to be one half of the period of the data bits in the input data signal and the clock signal remains synchronized to the center of the data state transitions of the input data signal.

US pre-grant publication No. 20060031701 discloses a CMOS burst mode clock data recovery circuit using frequency tracking method. This prior art provides a burst mode clock data recovery circuit for extracting clock information and data information from transmitted data to process data synchronized with clock. However, this prior art also adopts close-loop approach and is at the expense of T/4 margin.

### SUMMARY OF THE INVENTION

It is an object of the present invention to provide an asynchronous serial bus data reception system with input-signal recovery circuit to fast and precisely reconstruct data sent from a transmission end circuit.

Accordingly, the present invention provides an input-signal recovery circuit receiving a received data signal and a delay control signal to control a buffered pulse signal. The buffered pulse signal is used as a timing clock for processing the received data signal. The input-signal recovery circuit comprises:

a data switch detector comprising an input end receiving the received data signal and an output end;

a pulse generator comprising a plurality of logic circuits and receiving the received data signal and the delay control signal to generate a plurality of delayed pulse signals;

a plurality of switches, each of the switch electrically connected to one corresponding logic circuit, wherein one of the switches is selectively turned on by the data switch detector,

wherein the data switch detector selects an output pulse signal from a specific switch when the data switch detector senses a logic state change in the received data signal.

Accordingly, the present invention provides an asynchronous serial bus data reception system comprising:

at least one input buffer electrically connected to a transmission end circuit and generating a received data signal after receiving a data signal from the transmission end circuit;

a clock generator electrically connected to an external crystal oscillator and generating a continuous clock signal;

a frequency divider electrically connected to the clock generator and outputting a frequency-division signal;

a timing compensation unit electrically connected to the frequency divider and receiving the frequency-division signal, the timing compensation unit outputting a delay control signal to control half-period delay; and

at least one input-signal recovery circuit electrically connected to the timing compensation unit and receiving the delay control signal,

wherein the input-signal recovery circuit processes the received data signal according to the delay control signal for controlling half-period delay.

### BRIEF DESCRIPTION OF DRAWING

The features of the invention believed to be novel are set forth with particularity in the appended claims. The invention itself, however, may be best understood by reference to the following detailed description of the invention, which describes an exemplary embodiment of the invention, taken in conjunction with the accompanying drawings, in which:

FIG. 1 shows a schematic diagram of a related art synchronous fully differential bus transceiver system.

FIG. 2 depicts the data signal and the clock signal in FIG. 1.

FIG. 3 depicts the data signal and the clock signal with reduced setup time and hold time in FIG. 1.

FIG. 4 shows the schematic diagram of a related-art asynchronous serial bus transceiver system.

FIG. 5 depicts the data signal and the clock signal in FIG. 4.

FIG. 6 depicts the data signal and the clock signal with reduced setup time in FIG. 5.

FIG. 7 depicts the data signal and the clock signal with reduced hold time in FIG. 5.

FIG. 8 shows the schematic diagram of another related-art asynchronous serial bus transceiver system.

FIG. 9 shows the triggering clock signal and the Sync pattern in asynchronous serial bus transceiver system of FIG. 8.

FIG. 10 shows the mis-alignment of the triggering clock signal and data signal in asynchronous serial bus transceiver system of FIG. 8.

FIG. 11 shows the schematic diagram of the asynchronous serial bus data reception system according to the present invention.

FIG. 12 shows the detailed circuit of the timing compensation unit of the present invention.

FIG. 13 shows the timing diagram of the pulse signals for the half-period generator in FIG. 12.

FIG. 14 shows the detailed circuit diagram for the input-signal recovery circuit according to the present invention.

FIG. 15 shows waveforms explaining the relationship between the received data signal Dr and output of the data switch detector.

FIG. 16 shows the steps for determining the turning on/off of switches SW05 to SW75.

FIGS. 17a and 17b show two examples of using output from switches SW05 to SW75 as timing clock.

FIG. 18 shows detailed circuit diagram for the input-signal recovery circuit according to another preferred embodiment of the present invention.

FIG. 19 shows waveforms explaining the relationship between the received data signal Dr and output of the data switch detector for the circuit in FIG. 18.

FIGS. 20a and 20b show two examples of using output from switches SW05 to SW75 as timing clock for the circuit in FIG. 18.

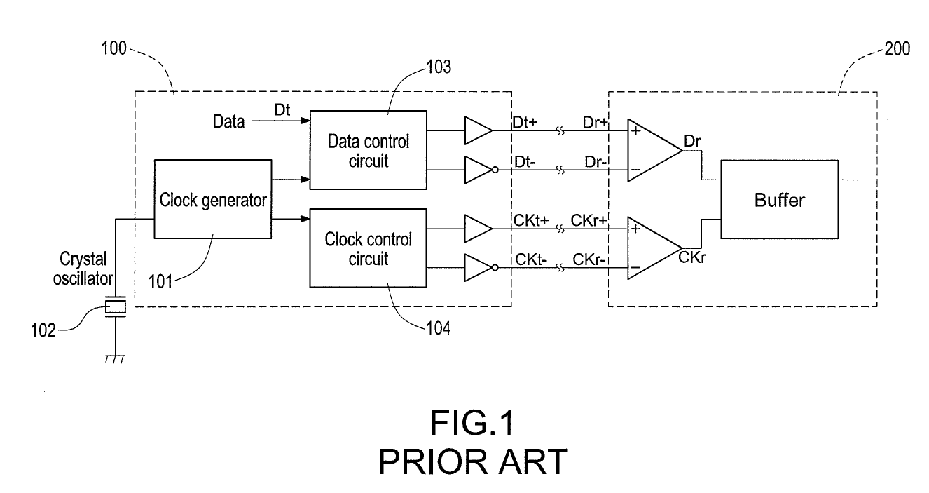

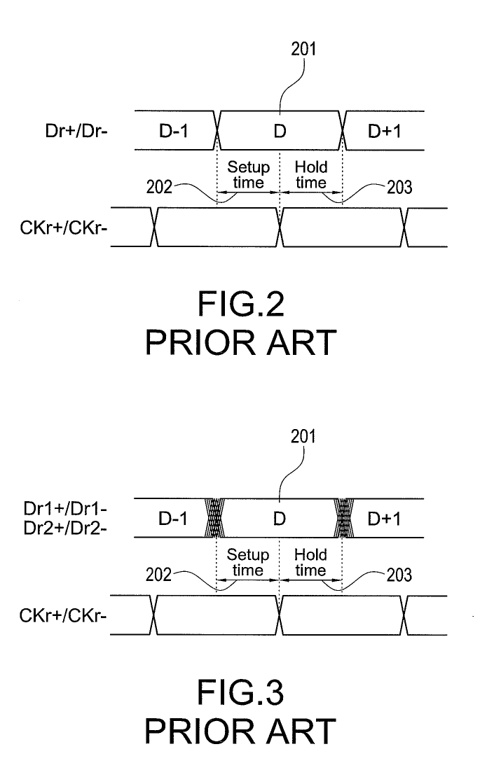

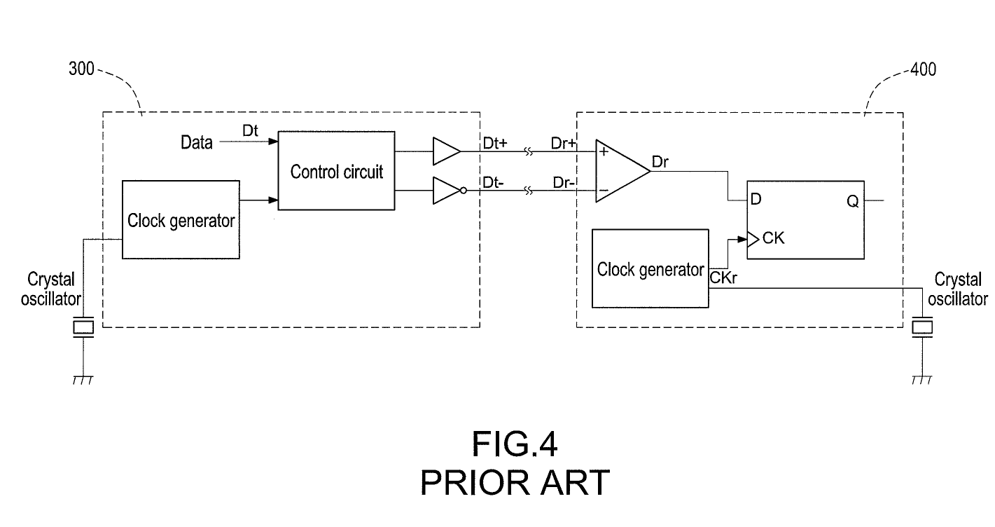

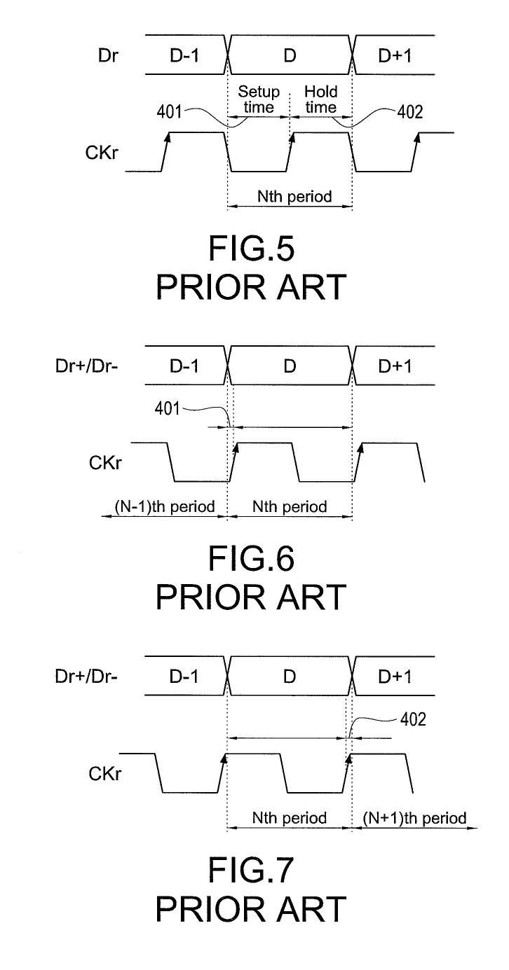

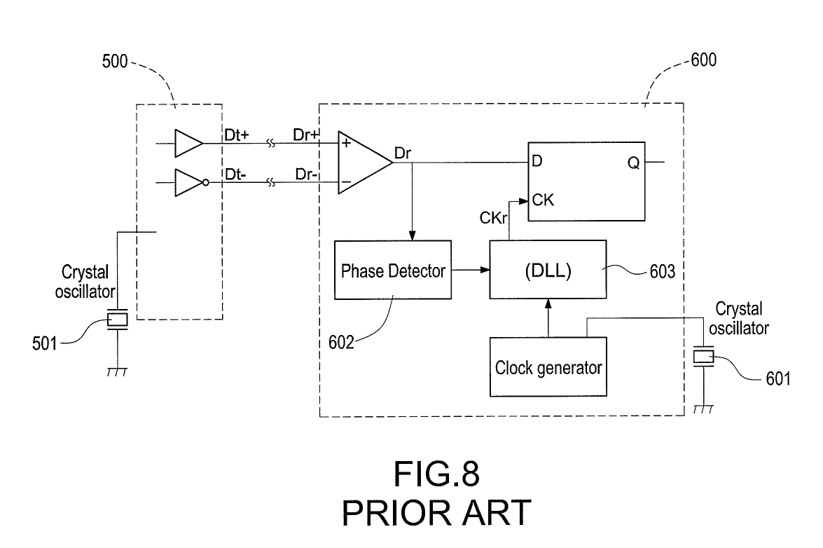

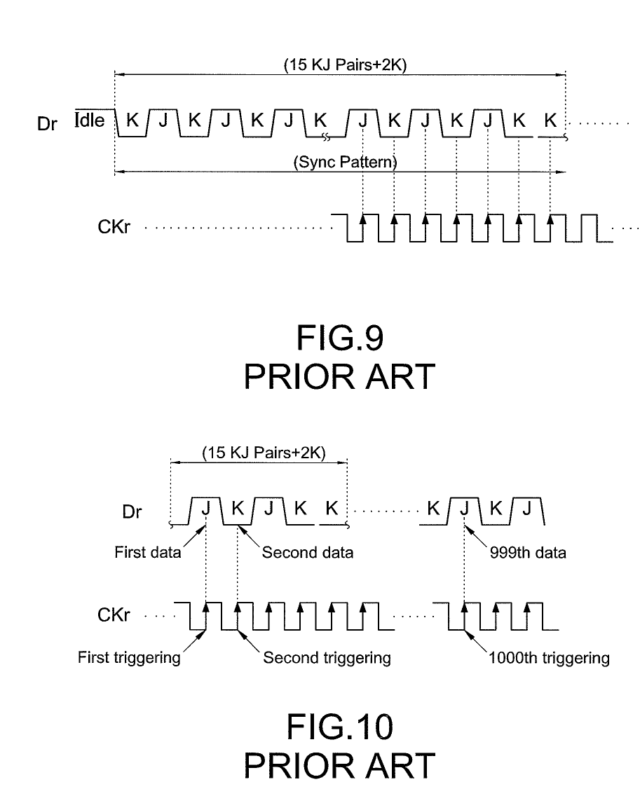

### DETAILED DESCRIPTION OF THE INVENTION

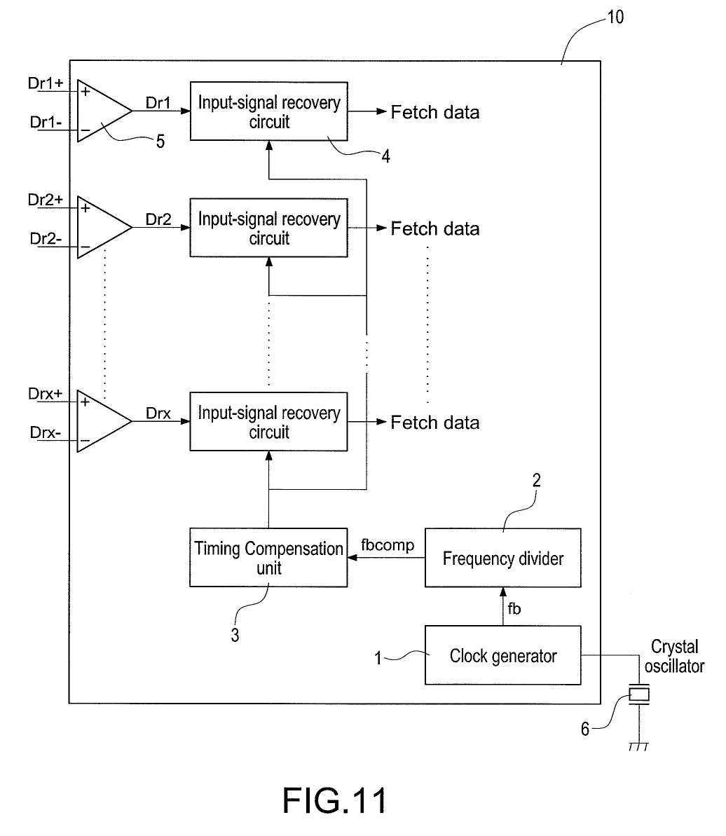

FIG. 11 shows the schematic diagram of the asynchronous serial bus data reception system according to the present invention. The data reception system 10 according to the present invention comprises a clock generator 1, a frequency divider 2, a timing compensation unit 3, at least one input-signal recovery circuit 4 and at least one input buffer 5.

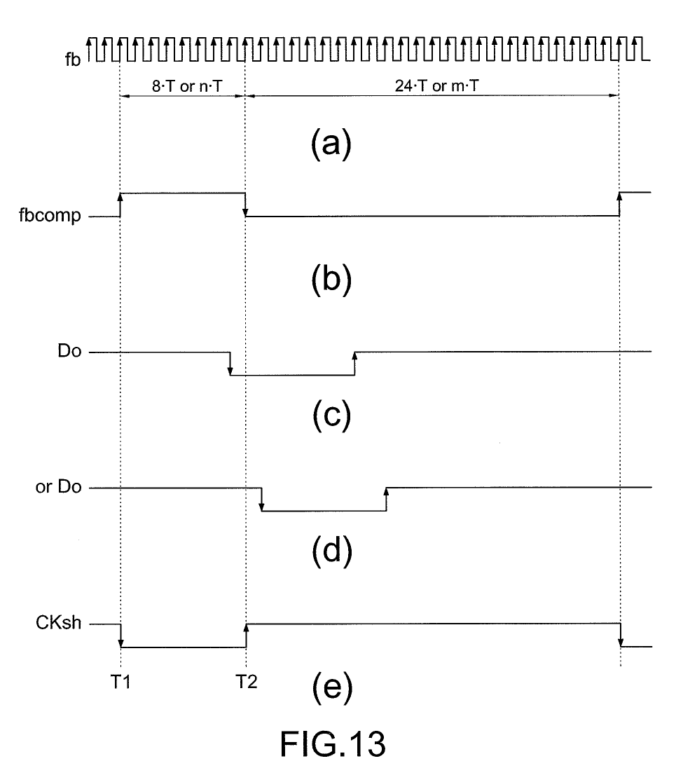

The clock generator 1 is electrically connected to an external crystal oscillator 6, which is independent to the crystal oscillator in transmitter system. The clock generator 1 receives an oscillation frequency of the external crystal oscillator 6, and outputs a continuous clock signal fb as shown in FIG. 13a.

The frequency divider 2 is electrically connected to the clock generator 1 and receives the continuous clock signal fb to output a delayed frequency-division signal fbcomp with lower frequency. Provided that one period of the frequency-division signal fbcomp contains n signal fb width in logic high state and contains m signal fb width in logic low state, the optimal design is m=3×n, as shown in FIG. 13b.

The timing compensation unit 3 is electrically connected to the frequency divider 2 and outputs a half-period delay control signal upon receiving the frequency-division signal fbcomp, hereinafter the half-period delay control signal is referred to delay control signal for simplicity.

The at least one input-signal recovery circuit 4 is electrically connected to the timing compensation unit 3 and the at least one input buffer 5, respectively. The input-signal recovery circuit 4 receives the delay control signal to recover the output data signal Dr output from the input buffer 5.

The at least one input buffer 5 is electrically connected to a transmission end circuit (not shown) and one input-signal recovery circuit 4. The input buffer 5 processes signals Dr1+ and Dr1− from the transmission end circuit and generated a received output data signal Dr, hereinafter the received output data signal Dr is referred to received data signal Dr for simplicity.

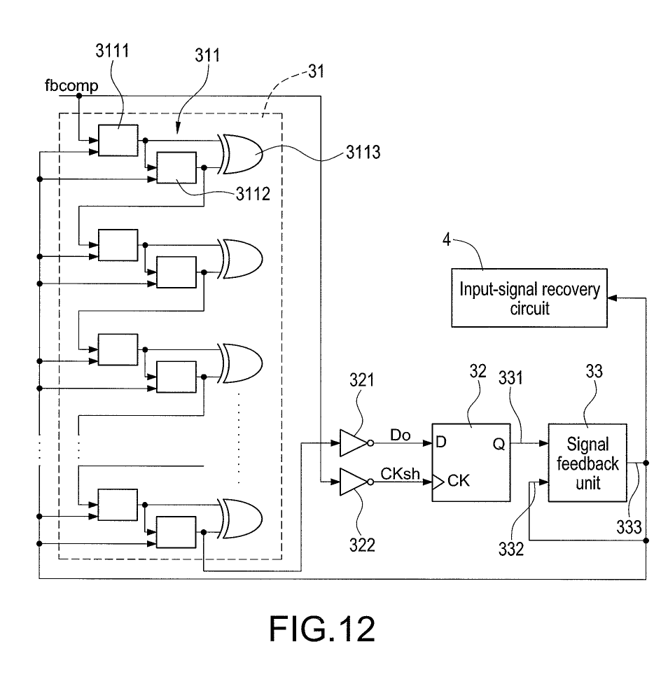

With reference to FIGS. 12 and 13 and further to FIG. 11, the timing compensation unit 3 comprises a delay generator 31, a flip-flop 32 and a signal feedback unit 33.

The delay generator 31 comprises a plurality of (8 in the shown example) logic units 311 and each logic unit 311 comprises two half-period generators 3111, 3112 and an exclusive OR (XOR) gate 3113. The outputs of the half-period generator 3111 and 3112 are connected to the two inputs of the XOR gate 3113. One input of the first half-period generator 3111 is connected to the output of the frequency divider 2. The output of the first half-period generator 3111 is also connected to one input of the second half-period generator 3112. The output of the second half-period generator 3112 is connected to one input of the first half-period generator 3111 in next-stage logic units 311. Following in this manner, the delay generator 31 can be provided.

The flip-flop 32 is a D-type flip-flop and the two input ends D and CK are electrically connected to the outputs of the first inverter 321 and the second inverter 322. The input of the first inverter 321 is connected to the output of the second half-period generator 3112 in the last stage logic unit 311. The input of the second inverter 322 is connected to the output of the frequency divider 2. The output Q of the flip-flop 32 is electrically connected to the first input end 331 of the signal feedback unit 33.

The signal feedback unit 33 comprises a first input end 331, a second input end 332 and an output end 333, where the first input end 331 is electrically connected to the output Q of the flip-flop 32, the output end 333 is fed back to the second input end 332, one input end for each of the first half-period generator 3111 and the second half-period generator 3112, and the input-signal recovery circuit 4 shown in FIG. 11.

The rising edge of the frequency-division signal fbcomp is delayed with the sixteen half-periods (8 periods) provided by the first half-period generators 3111 and the second half-period generators 3112. The delayed frequency-division signal fbcomp (the signal D₀ shown in FIG. 12) is triggered by the falling edge of the frequency-division signal fbcomp (namely the rising edge of the output signal CKsh of the second inverter 322). More particularly, the rising edge of the output signal CKsh of the second inverter 322 triggers the signal D₀ output from the first inverter 321 to generate an indication signal Q₀ output through the output Q of the flip-flop 32. If the indication signal Q₀ output through the output Q is in logic low level, it means that the first half-period generator 3111 and the second half-period generator 3112 do not have enough delay time, as shown in FIG. 13c. The signal feedback unit 33 sends the delay control signal to each of the first half-period generators 3111 and the second half-period generators 3112 to prolong the delay thereof. On the contrary, if the indication signal Q₀ output through the output Q is in logic high level, it means that the first half-period generator 3111 and the second half-period generator 3112 do not have sufficiently short delay time, as shown in FIG. 13d. The signal feedback unit 33 sends the delay control signal to each of the first half-period generators 3111 and the second half-period generators 3112 to reduce the delay thereof.

The timing compensation unit 3 has sufficient time to generate the delay control signal before the transmission end circuit (not shown) sends data signal. The input-signal recovery circuit 4 then receives the data sent from the transmission end circuit (not shown) according to the delay control signal. The delay control signal for the first half-period generator 3111 and the second half-period generator 3112 can be adjusted during the course of data transmission.

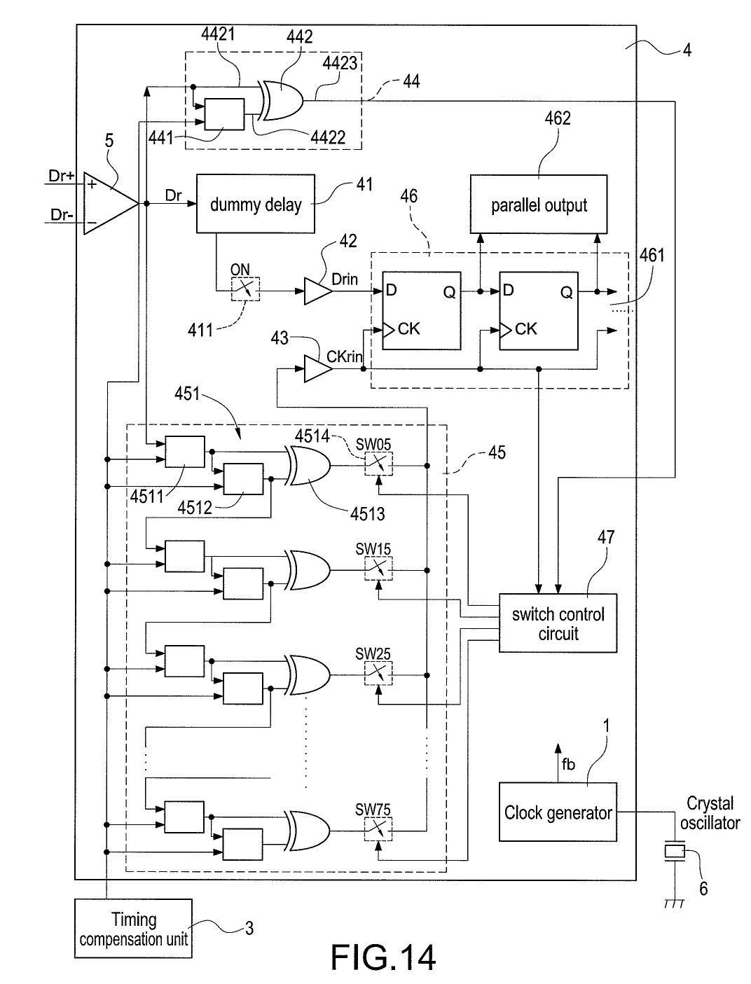

FIG. 14 shows the detailed circuit diagram for the input-signal recovery circuit 4 according to the present invention. The input-signal recovery circuit 4 comprises a dummy delay 41, a first buffer 42, a second buffer 43, a data switch detector 44, a pulse generator 45 and a serial data register 46.

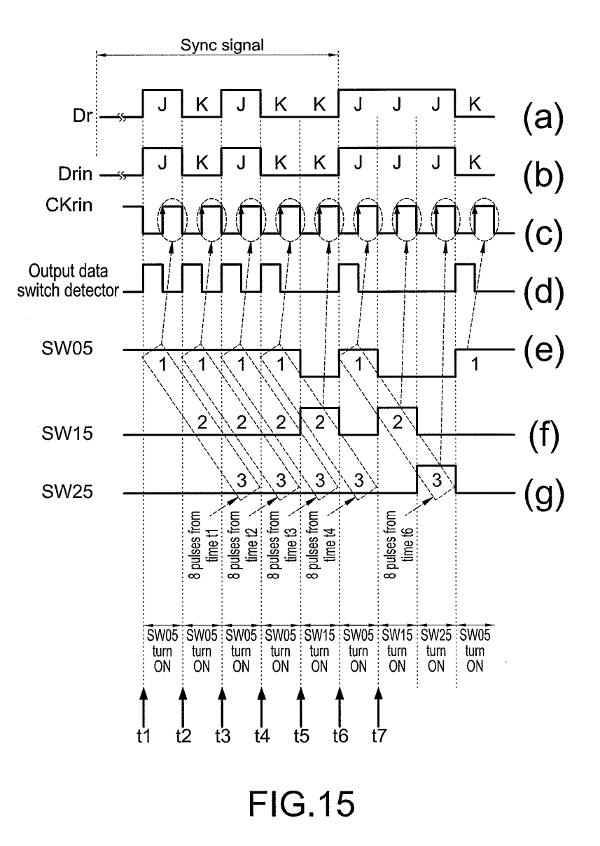

The input of the dummy delay 41 is electrically connected to the output of the input buffer 5, and the output of the dummy delay 41 is electrically connected to the input of a connection switch 411. As shown in FIG. 15a, the dummy delay 41 receives the received data signal Dr from the input buffer 5.

The first buffer 42 comprises an input end and an output end, where the input end is electrically connected to the connection switch 411 and generates a buffered data Drin as shown in FIG. 15b.

The second buffer 43 comprises an input end and an output end, where the input end is electrically connected to the output of the pulse generator 45, and the output end is electrically connected to the input of the serial data register 46. The second buffer 43 receives one of the pulse signals from the pulse generator 45 as shown in FIG. 15e-15g, and generates a buffered pulse signal Ckrin as shown in FIG. 15c.

The data switch detector 44 comprises a half-period generator 441 and an XOR gate 442. The first input of the half-period generator 441 is electrically connected to the output of the input buffer 5 and the first input of the XOR gate 442. The output of the half-period generator 441 is electrically connected to the second input of the XOR gate 442. The second input of the half-period generator 441 is electrically connected to the output of the timing compensation unit 3. The output 4423 of the XOR gate 442 is electrically connected, through a switch control circuit 47, to the first switch (SW05), . . . and the eighth switch (SW75) in the pulse generator 45. The data switch detector 44 control the on/off of the first switch (SW05) to the eighth switch (SW75) according to the received data signal Dr from the input buffer 5.

The pulse generator 45 comprises a plurality of (8 in this example) logic circuits 451. Each of the logic circuits 451 comprises two half-period generators 4511, 4512 and an exclusive OR (XOR) gate 4513. The outputs of the half-period generators 4511 and 4512 are connected to the two inputs of the XOR gate 4513. The output of the XOR gate 4513 is electrically connected to the first switch (SW05), which is connected to the input of the second buffer 43. The first input of the first half-period generator 4511 is electrically connected to the output of the input buffer 5. The output of the first half-period generator 4511 is electrically connected to one input of the second half-period generator 4512. The output of the second half-period generator 4512 is electrically connected to one input of the first half-period generator 4511 in next-stage logic circuits 451. The other inputs of the first half-period generator 4511 and the second half-period generator 4512 are electrically connected to the output of the timing compensation unit 3 to receive the delay control signal. The pulse generator 45 receives the received data signal Dr from the input buffer 5 and the logic circuits 451 generate delayed pulse signals with different delay time. The delayed pulse signals are sent to the first switch (SW05) to the eighth switch (SW75) respectively, which will be detailed later.

The serial data register 46 comprises at least one D-type flip-flop, where each D-type flip-flop comprises a data input and a clock input. The data input is electrically connected to the output of the first buffer 42, and the clock input is electrically connected to the output of the second buffer 43. The serial data register 46 receives data from the first buffer 42 and the second buffer 43, and then output data through serial output 461 or parallel output 462.

The data switch detector 44 detects whether received data signal Dr has switching in time points t1, t2, t3, t4, t5, t6 . . . as shown in FIG. 15. The eight logic circuits 451 of the pulse generator 45 generate 8 pulse signals with delay to each other; and the 8 pulse signals are sent to the first switch (SW05), . . . and the eighth switch (SW75), respectively. Therefore, there are eight replica for the received data signal Dr, namely, the delay pulse signals sent to the first switch (SW05), . . . and the eighth switch (SW75).

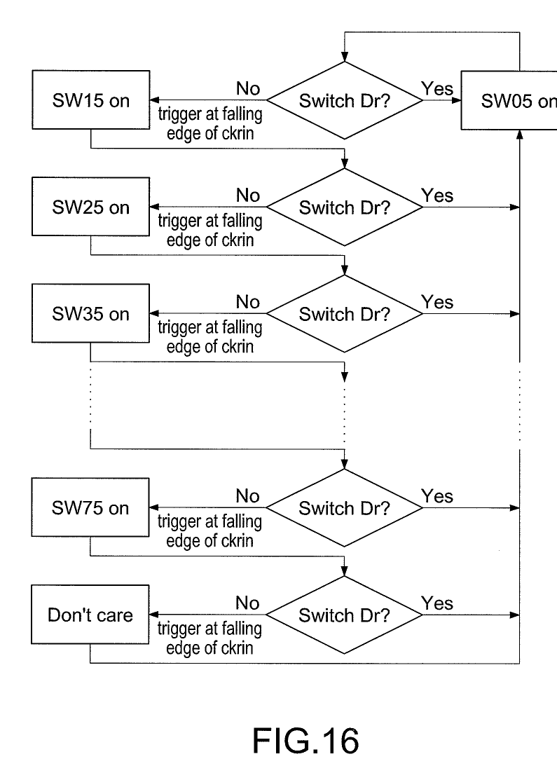

The data switch detector 44 selects the outputs from the pulse generator 45 to provide buffered pulse signal CKrin with 8 different delay times and half period width, where the 8 different delay times have minute difference for each other, as shown FIG. 15. With reference to FIGS. 15 and 16, the data switch detector 44 makes selection by following rules. When two successive received data signal Dr have not logic change (logic change means from 0 to 1 and vice versa), the buffered pulse signal CKrin is provided by the second switch SW15. When three received data signal Dr have not logic change, the buffered pulse signal CKrin is provided by the third switch SW25. The rule is also applied to more successive received data signal Dr without logic change. Once there is logic change in the two successive signals Dr, the buffered pulse signal CKrin is provided by the first switch SW05. Preferably, the received data signal Dr are pre-processed such that only at most seven successive logic one or zero are allowed. Therefore, the data switch detector 44 can provide buffered pulse signal CKrin with 8 different delay times. Moreover, the data switch detector 44 can be operated in cyclic manner and the data switch detector again selects the output of the first switch SW05 when there are nine successive received data signal Dr without logic change.

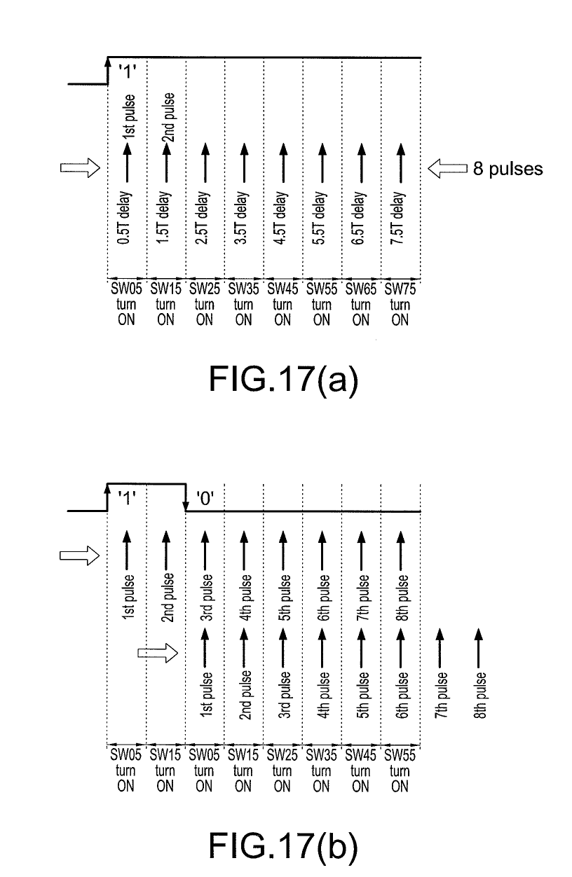

As shown in FIG. 17a, when the received data signal Dr changes from logic 0 to logic 1, the eight logic circuits 451 in the pulse generator 45 send eight delayed pulse signals to the first switch (SW05), . . . and the eighth switch (SW75), respectively. The eight delayed pulse signals are selected in turn by the data switch detector 44, in cyclic manner, to catch (trigger) the received data signal Dr. With reference to FIG. 17b, when a logic 0 data is detected in the received data signal Dr, similarly, the eight logic circuits 451 in the pulse generator 45 send eight delayed pulse signals to the first switch (SW05), . . . and the eighth switch (SW75), respectively. However, at this time, the data switch detector 44 will restart the cycle by turning on the first switch (SW05). Afterward, the buffered pulse signal Ckrin is provided by the pulse signals from the second switch SW15, the third switch SW25 . . . respectively. The buffered pulse signals Ckrin provided by the pulse signals of the first switch (SW05), . . . and the eighth switch (SW75) have minute difference therebetween. The data switch detector 44 can restart the cycle of selecting first switch (SW05), . . . and the eighth switch (SW75) according to the logic state in the received data signal Dr. Therefore, the input-signal recovery circuit 4 according to the present invention can prevent data error from error accumulation due to physical difference of crystal oscillators.

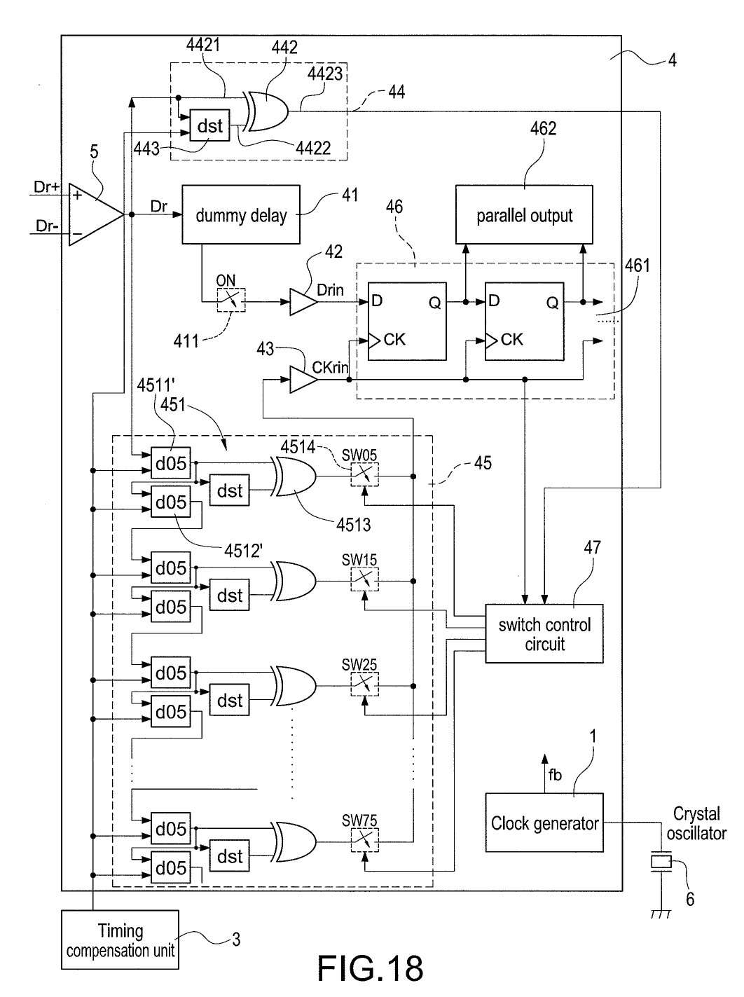

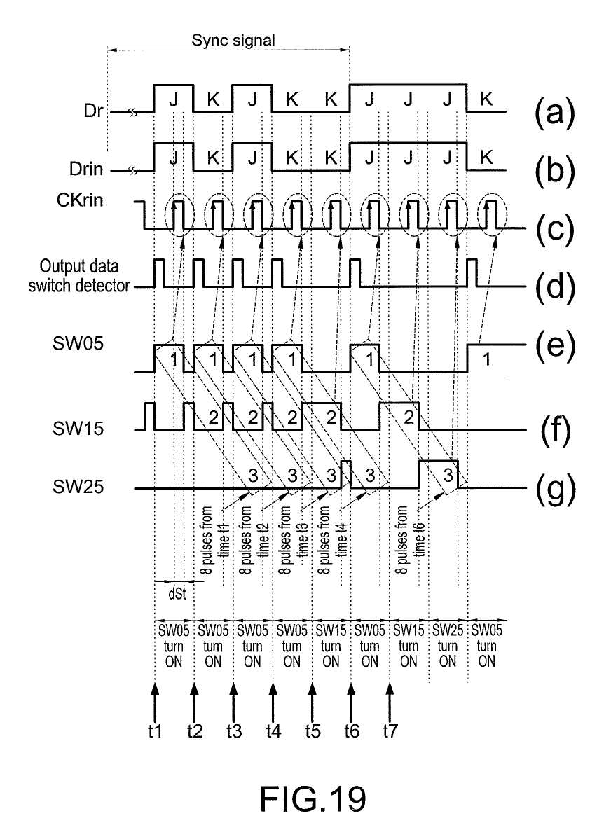

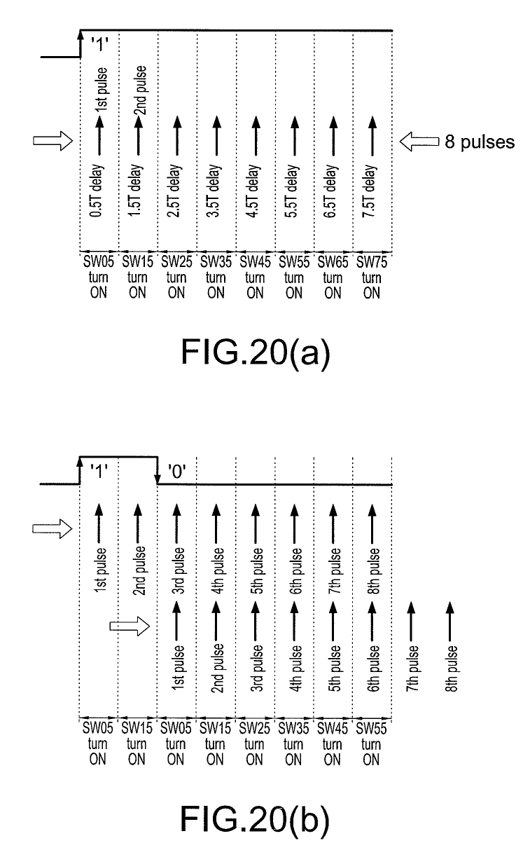

FIG. 18 shows detailed circuit diagram for the input-signal recovery circuit according to another preferred embodiment of the present invention. This preferred embodiment has circuit diagram similar to that in FIG. 14 except that a fixed-time delay unit dst is provided between the output of the first half-period generator 4511′ and the second input of the XOR gate 4513. Moreover, the input of the second half-period generator 4512′ is electrically connected to the output of the first half-period generator 4511′. The output of the second half-period generator 4512′ is electrically connected to the input of the first half-period generator 4511′ in next stage. Similarly, in a data switch detector 44, the half-period generator 441 is replaced by a fixed-time delay unit dst. FIG. 19 shows waveforms explaining the relationship between the received data signal Dr and output of the data switch detector for the circuit in FIG. 18. The buffered pulse signal Ckrin has turning-on time decided by the duration of the fixed-time delay unit dst. FIGS. 20a and 20b show two examples of using output from switches SW05 to SW75 as timing clock for the circuit in FIG. 18. It should be noted that, in a limiting case, the fixed-time delay unit dst provides exactly half period delay. In this case, the embodiment shown in FIG. 18 has the same effect as that shown in FIG. 14. When the fixed-time delay unit dst provides a delay time less than half period, with reference to FIG. 19, the second switch SW15 is turned on earlier. As a result, the buffered pulse signal Ckrin becomes shorter. The serial data register has enough time to catch the output data signal Dr if it is triggered by the falling edge of the buffered pulse signal Ckrin.

What is claimed is:

1. An input-signal recovery circuit receiving a received data signal and a delay control signal to control a buffered pulse signal, the buffered pulse signal used as a timing clock for processing the received data signal, the input-signal recovery circuit comprising:
a data switch detector comprising an input end receiving the received data signal and an output end;
a pulse generator comprising a plurality of logic circuits and receiving the received data signal and the delay control signal to generate a plurality of delayed pulse signals;
a plurality of switches, each of the switch electrically connected to one corresponding logic circuit, wherein one of the switches is selectively turned on by the data switch detector,
wherein the data switch detector selects an output pulse signal from a specific switch when the data switch detector senses a logic state change in the received data signal.

2. The input-signal recovery circuit in claim 1, further comprising:
a dummy delay having an input end for receiving the received data signal and an output end electrically connected to a connection switch;
a first buffer having an input end electrically connected to an output of the connection switch and an output end, the first buffer generating a buffered data and sending the buffered through the output end thereof;
a second buffer having an input end electrically connected to the pulse generator and an output end.

3. The input-signal recovery circuit in claim 2, wherein each of the logic circuit comprises
a first half-period generator;
a second half-period generator; and
an XOR gate, wherein
an output of the first half-period generator and an output of the second half-period generator are electrically connected to two inputs of the XOR gate;
an output of the XOR gate is electrically connected to one corresponding switch;
one output of the second half-period generator is electrically connected to an input of a first half-period generator in next stage;
one output of the first half-period generator is electrically connected to an input of the second half-period generator at the same stage;
an input of the first half-period generator at a first stage is electrically connected to the received data signal; and
all of the first half-period generators and the second half-period generators receive the delay control signal.

4. The input-signal recovery circuit in claim 3, wherein the output of the XOR gate is electrically connected to an input of one corresponding switch, and an output of the corresponding switch is connected to the input end of the second buffer.

5. The input-signal recovery circuit in claim 4, wherein the data switch detector comprises a half-period generator and an XOR gate,
wherein an input of the half-period generator is electrically connected to the received data signal and electrically connected to a first input end of the XOR gate, an output of the half-period generator is electrically connected to a second input end of the XOR gate, an output signal of the XOR gate is used to control the switches.

6. The input-signal recovery circuit in claim 2, further comprising:
a serial data register electrically connected to the output end of the first buffer and the output end of the second buffer, respectively.

7. The input-signal recovery circuit in claim 6, wherein the serial data register comprises at least one D-type flip flop.

8. The input-signal recovery circuit in claim 2, wherein each of the logic circuit comprises:
a first half-period generator;
a second half-period generator;
a fixed-time delay unit, and
an XOR gate, wherein
an output of the first half-period generator is electrically connected to an input of the second half-period generator, an input of the fixed-time delay unit and an input of the XOR gate;
an output of the XOR gate is electrically connected to one corresponding switch;
one output of the second half-period generator is electrically connected to an input of a first half-period generator in next stage;
an output of the fixed-time delay unit is electrically connected to another input of the is electrically connected to the XOR gate;
an input of the first half-period generator at a first stage is electrically connected to the received data signal; and
all of the first half-period generators and the second half-period generators receive the delay control signal.

9. An asynchronous serial bus data reception system comprising:
at least one input buffer electrically connected to a transmission end circuit and generating a received data signal after receiving a data signal from the transmission end circuit;
a clock generator electrically connected to an external crystal oscillator and generating a continuous clock signal;
a frequency divider electrically connected to the clock generator and outputting a frequency-division signal;
a timing compensation unit electrically connected to the frequency divider and receiving the frequency-division signal, the timing compensation unit outputting a delay control signal to control half-period delay; and
at least one input-signal recovery circuit electrically connected to the timing compensation unit and receiving the delay control signal,
wherein the input-signal recovery circuit processes the received data signal according to the delay control signal for controlling half-period delay;
wherein the input-signal recovery circuit comprises:
a data switch detector comprising an input end receiving the received data signal and an output end;
a pulse generator comprising a plurality of logic circuits and receiving the received data signal and the delay control signal to generate a plurality of delayed pulse signals;
a plurality of switches, each of the switch electrically connected to one corresponding logic circuit, wherein one of the switches is selectively turned on by the data switch detector,
wherein the data switch detector selects an output pulse signal from a specific switch when the data switch detector senses a logic state change in the received data signal.

10. The asynchronous serial bus data reception system in claim 9, wherein the input-signal recovery circuit further comprises:
a dummy delay having an input end for receiving the received data signal and an output end electrically connected to a connection switch;
a first buffer having an input end electrically connected to an output of the connection switch and an output end, the first buffer generating a buffered data and sending the buffered through the output end thereof;
a second buffer having an input end electrically connected to the pulse generator and an output end.

11. The asynchronous serial bus data reception system in claim 10, wherein each of the logic circuit comprises
a first half-period generator;
a second half-period generator; and
an XOR gate, wherein
an output of the first half-period generator and an output of the second half-period generator are electrically connected to two inputs of the XOR gate;
an output of the XOR gate is electrically connected to one corresponding switch;
one output of the second half-period generator is electrically connected to an input of a first half-period generator in next stage;
one output of the first half-period generator is electrically connected to an input of the second half-period generator at the same stage;
an input of the first half-period generator at a first stage is electrically connected to the received data signal; and
all of the first half-period generators and the second half-period generators receive the delay control signal.

12. The asynchronous serial bus data reception system in claim 11, wherein the output of the XOR gate is electrically connected to an input of one corresponding switch, and an output of the corresponding switch is connected to the input end of the second buffer.

13. The asynchronous serial bus data reception system in claim 12, wherein the data switch detector comprises a half-period generator and an XOR gate,
wherein an input of the half-period generator is electrically connected to the received data signal and electrically connected to a first input end of the XOR gate, an output of the half-period generator is electrically connected to a second input end of the XOR gate, an output signal of the XOR gate is used to control the switches.

14. The asynchronous serial bus data reception system in claim 10, further comprising:
a serial data register electrically connected to the output end of the first buffer and the output end of the second buffer, respectively.

15. The asynchronous serial bus data reception system in claim 14, wherein the serial data register comprises at least one D-type flip flop.
